(19) United States
(12) Patent Application Publication
(10) Pub. No.: US 2023/0299013 A1
(43) Pub. Date: Sep. 21, 2023

(54) MICROELECTRONIC ASSEMBLIES INCLUDING STIFFENERS

(71) Applicant: Intel Corporation, Santa Clara, CA (US)

(72) Inventors: Abdallah Bacha, Munich (DE); Bernd Waidhas, Pettendorf (DE); Eduardo De Mesa, Munich (DE); Carlton Hanna, Santa Jose, CA (US); Mohan Prashanth Javare Gowda, Ottobrunn (DE)

(73) Assignee: Intel Corporation, Santa Clara, CA (US)

(21) Appl. No.: 17/698,365

(22) Filed: Mar. 18, 2022

(51) Int. Cl. H01L 23/00; H01L 23/498; H01L 23/538; H01L 25/065; H01L 25/00

(52) U.S. Cl. CPC H01L 23/562; H01L 23/49816; H01L 23/5386; H01L 24/32; H01L 23/5384; H01L 24/16; H01L 25/0655; H01L 25/50; H01L 24/73; H01L 24/81; H01L 2224/16227; H01L 2924/15311; H01L 2224/32225; H01L 2224/73204

(57) ABSTRACT

Disclosed herein are microelectronic assemblies, as well as related apparatuses and methods. In some embodiments, a microelectronic assembly may include a substrate; and a microelectronic subassembly electrically coupled to the substrate by interconnects, the microelectronic subassembly including an interposer having a surface; a first die electrically coupled to the surface of the interposer; a second die electrically coupled to the surface of the interposer; and a stiffener ring coupled to the surface of the interposer along the perimeter of the interposer.

### BACKGROUND

Package substrates in integrated circuit (IC) packages are traditionally used to route electrical connections between a die and a circuit board. Dies and other functional components and elements may be disposed on a face of a package substrate. For example, stiffeners may be disposed on a face of the package substrate along with the die to prevent warpage, which is especially useful in coreless, ultra-thin core (UTC), and wafer level integrated circuit products.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a side, cross-sectional view of an exemplary microelectronic assembly, in accordance with various embodiments.

FIG. 1B is a bottom view of a substrate of the exemplary microelectronic assembly of FIG. 1A, in accordance with various embodiments.

FIG. 2A is a side, cross-sectional view of another exemplary microelectronic assembly, in accordance with various embodiments.

FIG. 2B is a bottom view of a substrate of the exemplary microelectronic assembly of FIG. 2A, in accordance with various embodiments.

FIG. 3A is a side, cross-sectional view of another exemplary microelectronic assembly, in accordance with various embodiments.

FIGS. 3B-3D are bottom views of substrates of the exemplary microelectronic assembly of FIG. 3A, in accordance with various embodiments.

FIG. 4A is a side, cross-sectional view of another exemplary microelectronic assembly, in accordance with various embodiments.

FIG. 4B is a bottom view of a substrate of the exemplary microelectronic assembly of FIG. 4A, in accordance with various embodiments.

FIG. 5 is a flow diagram of an example method of manufacturing a microelectronic assembly, in accordance with various embodiments.

FIG. 6A is a side, cross-sectional view of an exemplary microelectronic assembly, in accordance with various embodiments.

FIG. 6B is a top, cross-sectional view along the A-A′ line of a substrate of the exemplary microelectronic assembly of FIG. 6A, in accordance with various embodiments.

FIG. 7A is a side, cross-sectional view of another exemplary microelectronic assembly, in accordance with various embodiments.

FIGS. 7B-7D are top, cross-sectional view along the B-B′ line of substrates of the exemplary microelectronic assembly of FIG. 7A, in accordance with various embodiments.

FIGS. 8A-8C are side, cross-sectional views of an exemplary microelectronic assemblies, in accordance with various embodiments.

FIG. 9 is a flow diagram of an example method of manufacturing a microelectronic assembly, in accordance with various embodiments.

FIG. 10 is a top view of a wafer and dies that may be included in a microelectronic assembly, in accordance with any of the embodiments disclosed herein.

FIG. 11 is a cross-sectional side view of an IC device that may be included in a microelectronic assembly, in accordance with any of the embodiments disclosed herein.

FIG. 12 is a cross-sectional side view of an IC device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

Disclosed herein are microelectronic assemblies, as well as related apparatuses and methods. In some embodiments, a microelectronic assembly may include a substrate having a first surface and an opposing second surface; a die electrically coupled to the second surface of the substrate; and a stiffener attached to the first surface of the substrate configured to mitigate warpage of the die. In some embodiments, a microelectronic assembly may include a substrate, including a core and a stiffener in the core, wherein the stiffener is along a perimeter of the core; and a die electrically coupled to the substrate. In some embodiments, a microelectronic assembly may include a substrate; and a microelectronic subassembly electrically coupled to the substrate by interconnects, the microelectronic subassembly including an interposer having a surface; a first die electrically coupled to the surface of the interposer; a second die electrically coupled to the surface of the interposer; and a stiffener ring coupled to the surface of the interposer along the perimeter of the interposer.

Packaging semiconductor devices presents several challenges. One such challenge is encountered with the demand for miniaturization of semiconductor devices, continually requiring thinner form factors and multiple thermal processing steps. The resulting IC packages may suffer from warpage generated as a result of the mismatch in the coefficient of thermal expansion (CTE) between a thin die and a substrate. Fabrication of an IC package, is a multi-step process, which includes patterning, deposition, etching, and metallization. In final processing, a resulting IC die can be separated and packaged. A first plurality of solder bump structures (e.g., solder bumps, balls, pads, pillar bumps (e.g., copper pillar bumps), etc.) of a generally uniform size can be positioned between the die and a substrate, and the die and substrate can be heated to similar temperatures. The die can then be lowered onto the substrate, in order to mechanically and electrically couple the die to the substrate. Heat can be applied via a solder reflow process to re-melt the solder bumps and attach the die to the substrate. Attachment of the die to the substrate (i.e., primary substrate), to form the IC package, is referred to as a “first level interconnects” (FLI). The FLI may further be underfilled with a non-conductive adhesive to strengthen the mechanical connection between the die and the substrate. One or more such IC packages can be physically and electrically coupled to a secondary substrate, such as a printed circuit board (PCB) or a motherboard. Attachment of the IC package(s) directly to the secondary substrate, such as by soldering, is referred to as a “second level interconnects” (SLI).

Manufacturing of an IC package can involve multiple thermal cycling (or processing) steps. For instance, a substrate may be heated to add solder balls (e.g., flip-chip or controlled collapse chip connection (C4) solder balls) to a substrate. The substrate may again be heated one or more times for die placement and solder reflow. Another thermal cycle may be added if epoxy, for example, is used in the assembly process as an underfill material. An underfilling process, such as capillary-flow underfilling, relies upon capillary pressure of the underfill material, to flow between the substrate and the die. Yet another thermal cycle may be used to incorporate the IC package into an electronic assembly.

The multiple thermal cycles can lead to warpage of components of a resulting IC package or electronic assembly. Warpage refers to a bending or twist or general lack of flatness in an overall IC package, for example, including particularly the plane formed by solder joint locations. Such warpage is caused by a difference in CTE between one part or component and another. The problem of IC package warpage can be exacerbated in larger packages due to the larger size, and can also be exacerbated when soldering temperatures become higher and IC packages become thinner. Recently, the use of lead-free solders has become more prevalent on certain product types. This lead-free solder generally requires a higher soldering temperature than prior solders.

Warpage can pose a problem in forming solder joints, or interconnections, in IC packages. A lack of flatness can occur where the entire package warps so that it is curved or bent or otherwise non-flat. Lack of flatness in an IC package can cause various problems such as poor soldered joints between the IC package and a substrate, poor or no contact at the solder joints, undesirably pillowed joints, or intermittent contact at the solder joints. Such warpage can cause an IC package or an electronic assembly to fail. Package warpage is a significant challenge as it impacts the ability to handle the package during assembly steps. In addition, package warpage produces yield losses during reflow, which are typically caused by open (non-contacting) second layer interconnects in the locations having the maximum warpage-induced vertical displacement. As such, package warpage is therefore a major problem for package designs and, in particular, ultra-thin package designs.

One solution to the problem of IC package warpage has been the incorporation of a flat stiffener plate on top of the IC package to maintain planarity of the components. The stiffener plate takes the form essentially of a completely flat, entirely planar item generally having a constant thickness, and has a same shape as the IC package such that a perimeter of the stiffener plate is approximately a same size as a perimeter of the IC package when viewed from the top, although other shapes are contemplated. A central region of the stiffener plate may be cut out (include an aperture) to accommodate for one or more components, such as a die or dies, for example. Some stiffener plates include a frame or a ring attached to the perimeter of the stiffener plate, where the frame or ring is glued or soldered to a substrate along the perimeter of the IC package. Other stiffener plates may be attached to the substrate by adhesive (e.g., a discrete stiffener having a picture frame design), which can be a thermally set adhesive dispensed in liquid, semi-liquid or preformed formats. This packaging solution has several problems, including the tendency for the adhesive to “bleed” and spread onto bond surfaces, such as wire bond pads or other noble metal surfaces, such as ground rings or voltage rings, and adhere thereto which results in unsatisfactory electrical contacts and poor performance of the IC package. Various ones of the embodiments disclosed herein may help achieve improved performance of IC packages, with reduced warpage, relative to conventional approaches.

In the following detailed description, reference is made to the accompanying drawings that form a part hereof, wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques will exhibit rounded corners, surface roughness, and other features.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die,” an “IC die,” “a microelectronic component,” and “an electrical component.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

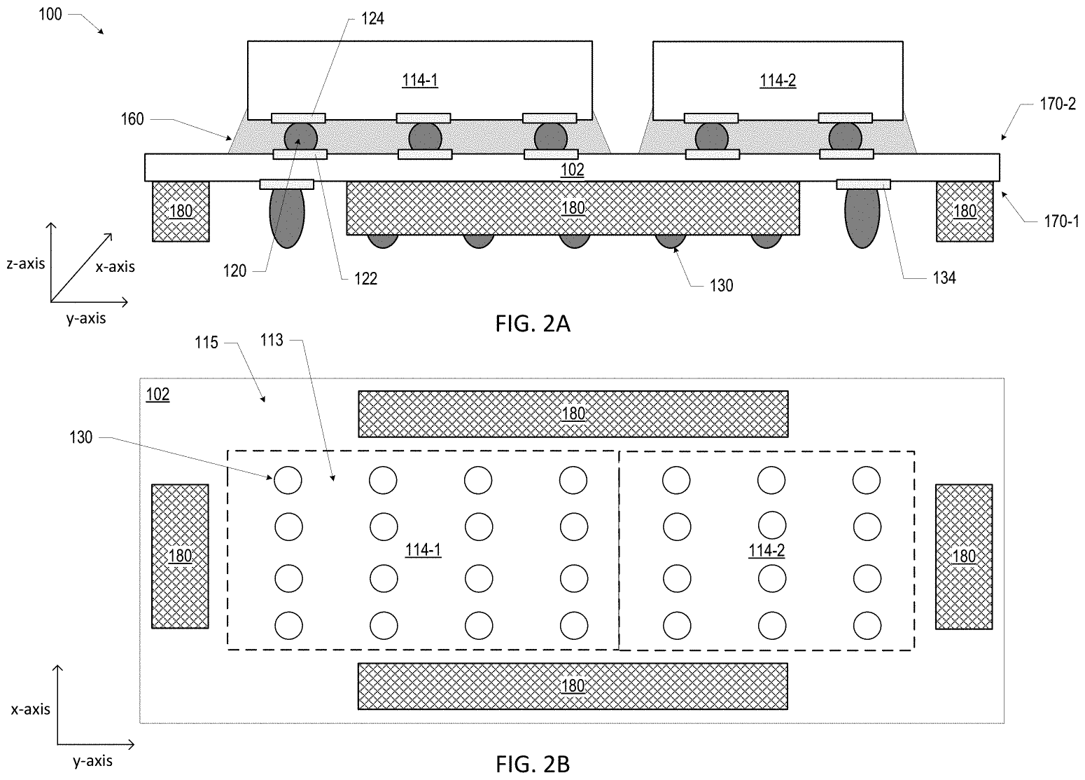

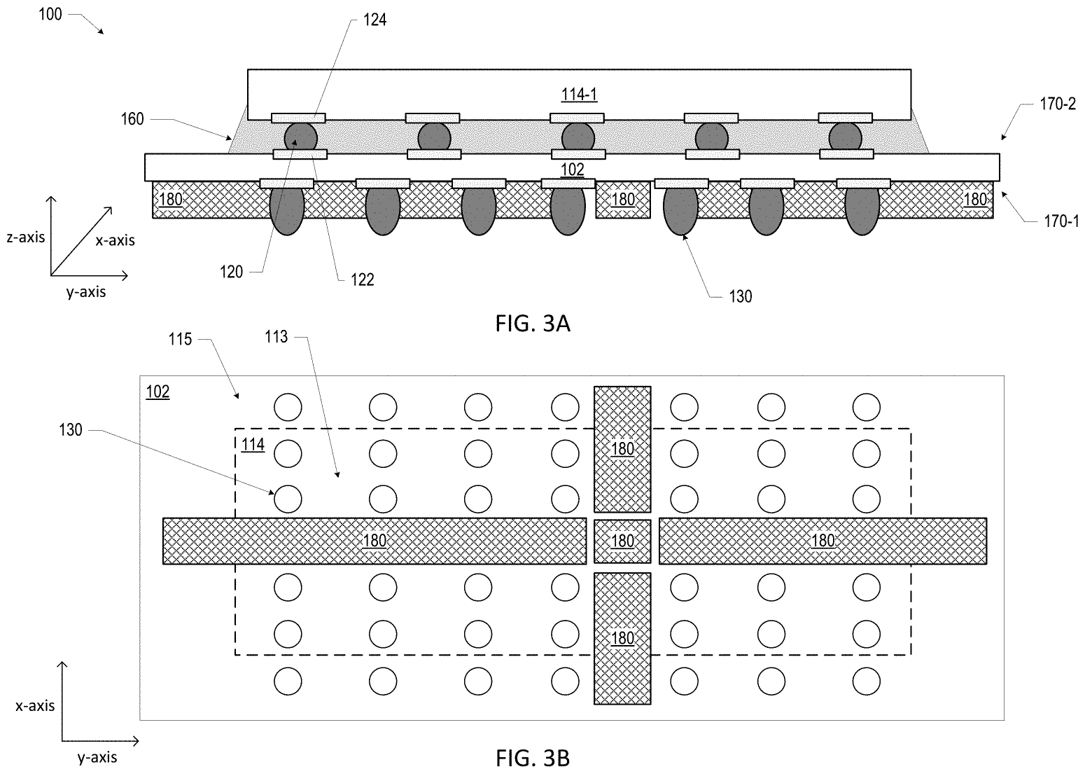

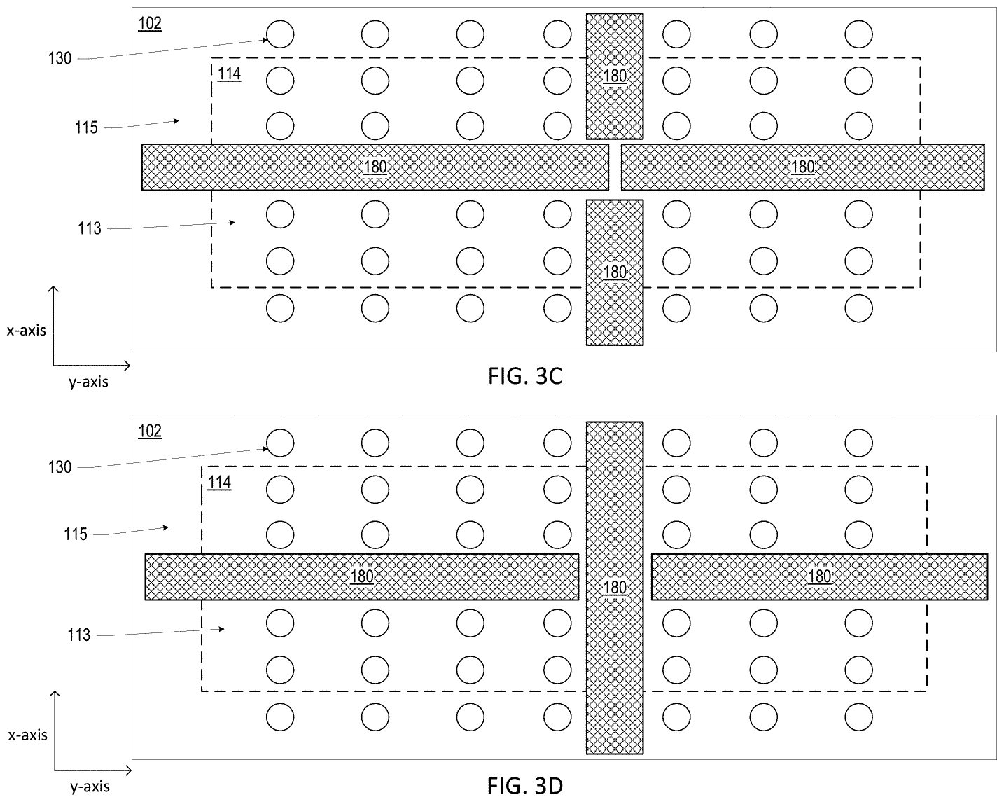

When used to describe a range of dimensions, the phrase “between X and Y” represents a range that includes X and Y. For convenience, the phrase “FIG. 2” may be used to refer to the collection of drawings of FIGS. 2A and 2B, the phrase “FIG. 3” may be used to refer to the collection of drawings of FIGS. 3A-3D, etc. Although certain elements may be referred to in the singular herein, such elements may include multiple sub-elements. For example, “an insulating material” may include one or more insulating materials. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

An “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

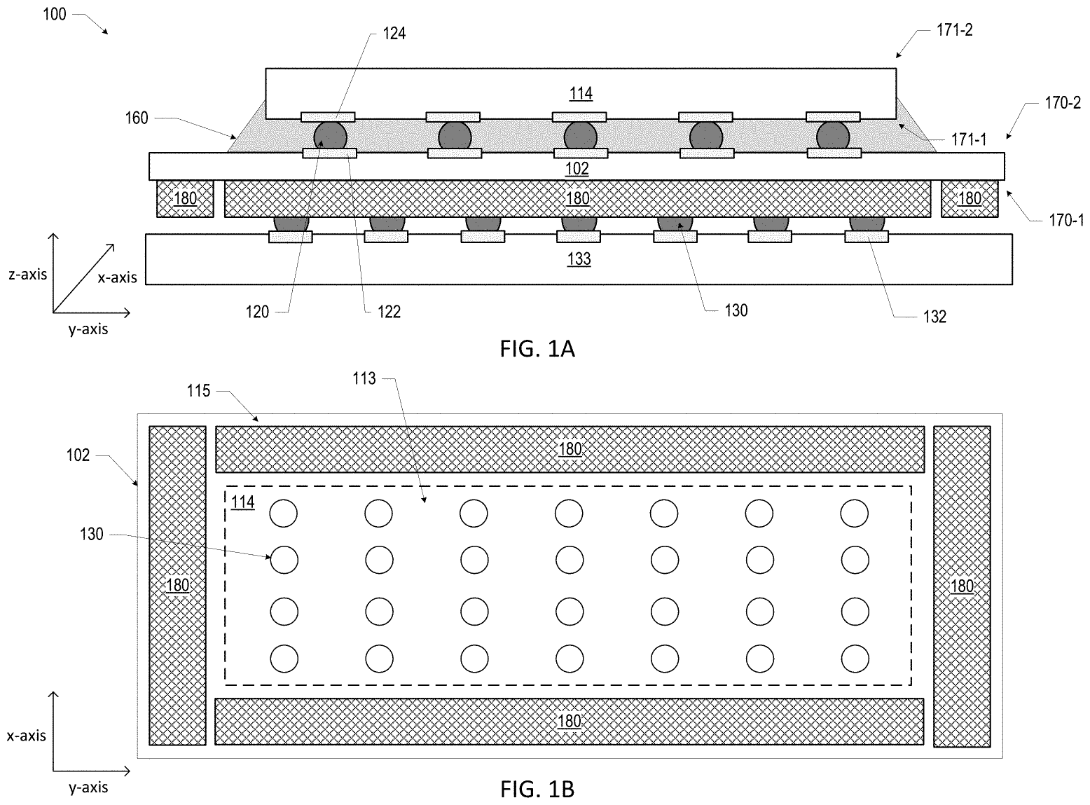

FIG. 1A is a side, cross-sectional view of a microelectronic assembly 100, in accordance with various embodiments. The microelectronic assembly 100 may include a substrate 102 with a die 114 and a stiffener 180 disposed thereon. The substrate 102 may have a bottom surface (e.g., a first surface 170-1) and an opposing top surface (e.g., a second surface 170-2). The die 114 may be disposed on a top surface 170-2 of the substrate 102 and the stiffener 180 may be disposed on a bottom surface 170-1. The stiffener 180 may be attached to the bottom surface 170-1 of the substrate 102 using any suitable technique, including an adhesive material (e.g., by gluing), a solder material (e.g., by soldering), or by thermal compression bonding.

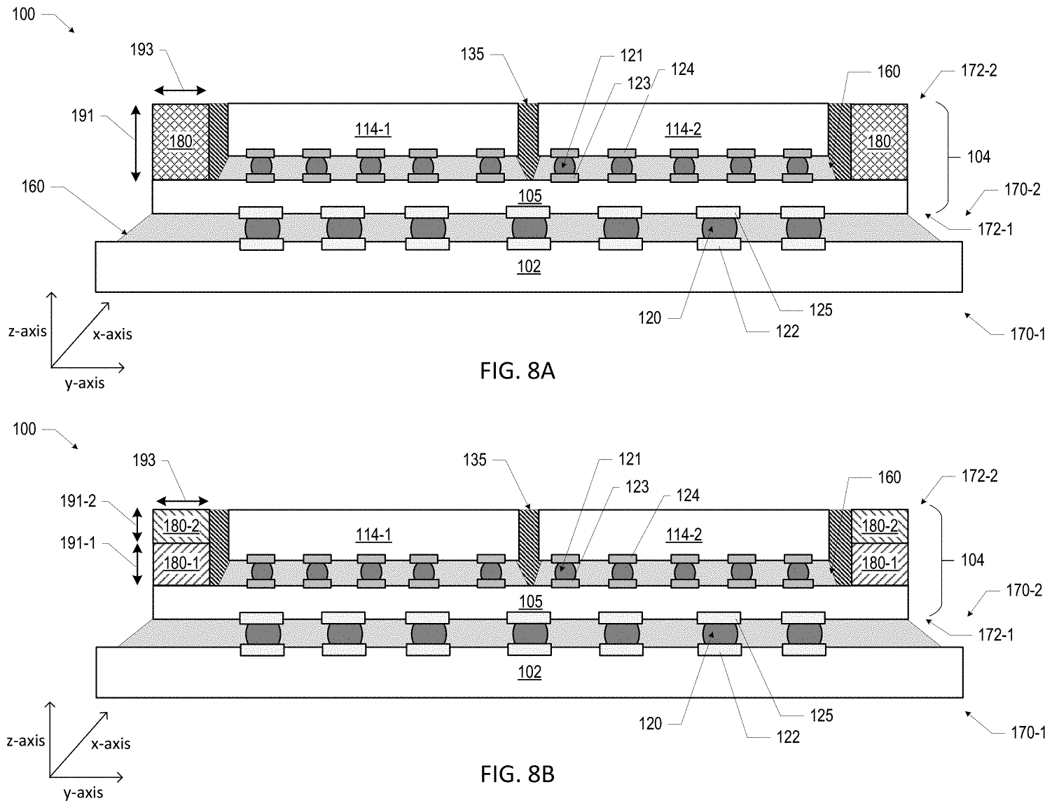

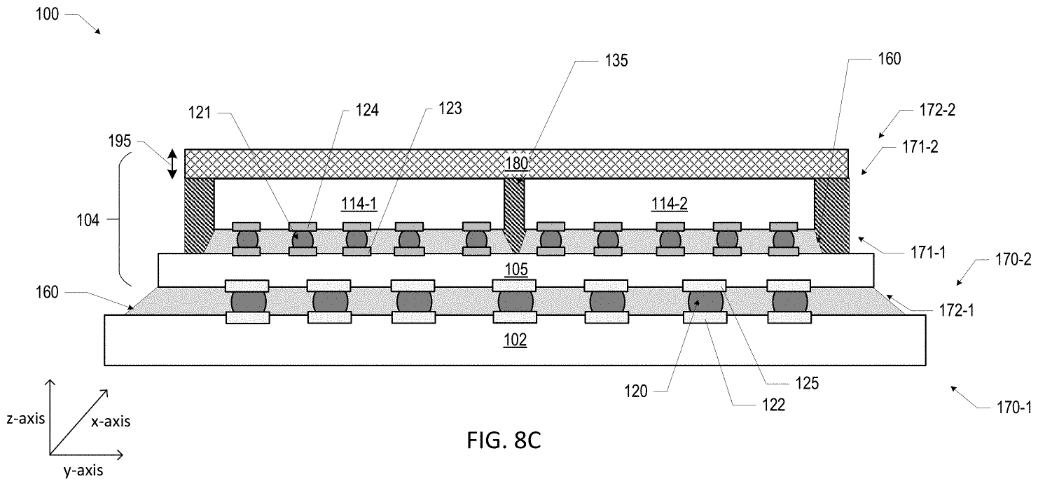

FIG. 1B is a bottom view of the substrate 102 and the stiffener 180 of the microelectronic assembly of FIG. 1A. FIG. 1B illustrates an interior portion 113 (e.g., as defined by an area within the dotted lines) and a perimeter 115 (e.g., as defined by an area outside the dotted lines). As used herein, an interior portion 113 refers to a footprint or surface area (e.g., length (y-direction) times width (x-direction)) that is covered by a die and/or other components on a top surface 170-2 of the substrate 102 or an other component (e.g., a microelectronic subassembly 104 as described below with reference to FIG. 8). As used herein, a perimeter 115 refers to a boundary or an outer edge of a substrate 102 or an other component (e.g., a microelectronic subassembly 104 as described below with reference to FIG. 8). In some embodiments, the stiffener 180 may include a continuous ring or frame that is positioned along a perimeter of the substrate 102. As used herein, the term “stiffener” may refer to one stiffener or may refer to a plurality of elements or sections that form the stiffener 180. As shown in FIG. 1B, the stiffener 180 may include four sections that substantially form a ring or a frame around a perimeter of the substrate 102. Although the stiffener 180 is shown in FIG. 1B as having four rectangular-shaped sections forming a rectangular ring, the stiffener 180 may include sections having any suitable shape forming any suitable frame. For example, a stiffener 180 may include sections having a square shape, a triangular shape, a circular shape, an oval shape, an oblong shape, a trapezoidal shape, or a rhombus shape arranged to form a circular frame, a square frame, a trapezoidal frame, or a rhombus frame, among others. As shown in FIGS. 1A and 1B, the sections of the stiffener 180 may have a length (e.g., y-direction), a width (e.g., x-direction), and a height (e.g., z-direction). Although the stiffener 180 is shown to have straight (e.g., perpendicular) walls, the stiffener 180 may have slanted or angled walls.

The stiffener 180 may have any suitable size and shape. The size and shape of the stiffener 180 on the bottom surface 170-1 may depend on a degree of counter warpage/balance needed to cancel or minimize warpage from the die 114 on the top surface 170-2. In some embodiments, a size and shape of a stiffener 180 may be determined using FEM simulation of the IC package (e.g., the die 114 coupled to the substrate 102), including the geometry and configuration of the IC package, as well as the combination of the IC package coupled to a circuit board 133. The dimensions of the stiffener 180 may also depend on a total volume of the die 114 on the top surface 170-2, the number of die 114 on the top surface 170-2, and a size and arrangement of the die 114 (e.g., whether the die 114 are stacked, etc.) on the top surface 170-2. For example, a total volume of the stiffener 180 may be between 50 percent and 110 percent of a total volume of the die 114 on a top surface 170-2. The dimensions of the stiffener 180 may further depend on a total surface area of the substrate 102. For example, a substrate 102 having a surface area between 30 millimeter by 30 millimeter may have a stiffener 180 with smaller overall dimensions than a substrate 102 having a surface area of 150 millimeter by 150 millimeter. In some embodiments, the length and width dimensions of the sections of the stiffener 180 may depend on their placement on a bottom surface 170-1 of the substrate 102. For example, the sections of the stiffener 180 placed along a width (e.g., x-direction) of the substrate 102 may have different dimensions than the sections of the stiffener 180 placed along a length (e.g., y-direction) of the substrate 102. For example, a section of the stiffener 180 along a length of the substrate 102 may have a width (e.g., x-dimension) equal to between 5 percent and 20 percent of the length of the substrate 102 and may have a length (e.g., y-direction) equal to between 50 percent and 100 percent of the length of the substrate 102. Similarly, a section of the stiffener 180 placed along a width (e.g., x-direction) of the substrate 102 may have a width equal to between 50 percent and 100 percent of the width of the substrate 102 and a length (e.g., y-dimension) equal to between 5 percent and 20 percent of the width (e.g., x-dimension) or the length (e.g., y-dimension) of the substrate 102. In some embodiments, some or all of the sections of the stiffener 180 may have the same dimensions. In some embodiments, some or all of the sections of the stiffener 180 may have different dimensions. In some embodiments, a height (e.g., z-direction or a thickness) of the stiffener 180 may be between 20% and 80% of a second level interconnect 130 height. In some embodiments, a height (e.g., z-direction) of the sections of the stiffener 180 may be a same dimension. In some embodiments, a height of the sections of the stiffener 180 may be different.

The stiffener 180 may be made from any suitable material, including a conductive material, such as a metal (e.g., copper or aluminum), an amorphous metal alloy (e.g., an alloy including titanium, zirconium, palladium, platinum, aluminum, or nickel), or a non-conductive material, such as, silicon, glass, or a ceramic, and made using any suitable technique, such as molding or sintering. In some embodiments, a material of the stiffener 180 may have a CTE between 2e-6 ppm/° C. and 17e-6 ppm/° C. The dimensions of the stiffener 180 also may depend on a material of the stiffener 180. For example, a stiffener 180 including an amorphous metal alloy having a greater hardness may have smaller dimensions compared to a stiffener 180 including a ceramic having a lesser hardness. In another example, a stiffener 180 having a CTE mismatch to the substrate 102 may have greater dimensions to counter warpage resulting from the CTE mismatch.

The die 114 may be electrically coupled to the substrate 102 by first level interconnects 120. The first level interconnects 120 may be surrounded by an underfill material 160 (e.g., the underfill material 160 may be disposed between the die 114 and the second surface 170-2 of the substrate 102). The substrate 102 may have first conductive contacts 134 on the first surface 170-1 (as shown in FIG. 2A) and second conductive contacts 122 on the second surface 170-2. The die 114 may include a bottom surface (e.g., a first surface 171-1) and an opposing top surface (e.g., a second surface 171-2). The die 114 may have the first surface 171-1 having conductive contacts 124. The conductive contacts 124 on the first surface 171-1 of the die 114 may be coupled to the conductive contacts 122 on the second surface 170-2 of the substrate 102 via the first level interconnects 120. In some embodiments, the first level interconnects 120 may include solder bumps or balls (as illustrated in FIG. 1); in other embodiments, the first level interconnects 120 may include copper pillars, wirebonds, metal-to-metal interconnects, or any other suitable interconnects surrounded by an underfill material 160. In some embodiments, the first level interconnects 120 may include an anisotropic conductive material, such as an anisotropic conductive film or an anisotropic conductive paste. An anisotropic conductive material may include conductive materials dispersed in a non-conductive material.

The underfill material 160 may be any suitable material. The underfill material 160 may be an insulating material, such as an appropriate epoxy material. In some embodiments, the underfill material 160 may include a capillary underfill, non-conductive film (NCF), or molded underfill. The underfill material 160 may be selected to have a CTE that may mitigate or minimize the stress between the die 114 and the substrate 102. In some embodiments, the underfill material 160 may include an epoxy flux that assists with soldering the die 114 to the substrate 102 when forming the first level interconnects 120, and then polymerizes and encapsulates the first level interconnects 120. In some embodiments, the CTE of the underfill material 160 may have a value that is intermediate to the CTE of the substrate 102 (e.g., the CTE of the dielectric material of the substrate 102) and a CTE of the die 114.

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 11. The conductive pathways in the dies 114 may be bordered by liner materials, such as adhesion liners and/or barrier liners, as suitable.

The substrate 102 may include an insulating material (e.g., a dielectric material formed in multiple layers, as known in the art) and one or more conductive pathways (not shown) to route power, ground, and signals through the dielectric material (e.g., including conductive traces and/or conductive vias, as shown). In some embodiments, the insulating material of the substrate 102 may be a dielectric material, such as an organic dielectric material, a fire retardant grade 4 material (FR-4), bismaleimide triazine (BT) resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the substrate 102 is formed using standard PCB processes, the substrate 102 may include FR-4, and the conductive pathways in the substrate 102 may be formed by patterned sheets of copper separated by build-up layers of the FR-4. The conductive pathways in the substrate 102 may be bordered by liner materials, such as adhesion liners and/or barrier liners, as suitable. In some embodiments, the substrate 102 may be a coreless substrate, a UTC substrate, a wafer level packaging, or any other suitable package designed to minimize z-height, as is known in the art. The substrate 102 may include conductive pathways (not shown) that allow power, ground, and other electrical signals to move between the die 114 and the substrate 102. In some embodiments, the die 114 and stiffener 180 may not be coupled to a substrate 102, but may instead be coupled to an interposer, a package substrate, or a circuit board, such as a PCB.

In some embodiments, the substrate 102 may be formed using a lithographically defined via packaging process. In some embodiments, the substrate 102 may be manufactured using standard organic package manufacturing processes, and thus the substrate 102 may take the form of an organic package. In some embodiments, the substrate 102 may be a set of redistribution layers formed on a panel carrier by laminating or spinning on a dielectric material, and creating conductive vias and lines by laser drilling or ablation and plating. In some embodiments, the substrate 102 may be formed on a removable carrier using any suitable technique, such as a redistribution layer technique. Any method known in the art for fabrication of the substrate 102 may be used, and for the sake of brevity, such methods will not be discussed in further detail herein.

In some embodiments, the substrate 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process.

The microelectronic assembly 100 may further include a circuit board 133. The first conductive contacts 134 (as shown in FIG. 2A) on the first surface 170-1 of the substrate 102 may be coupled to conductive contacts 132 on a surface of the circuit board 133 via second level interconnects 130. In some embodiments, the second level interconnects 130 may include solder balls (as illustrated in FIG. 1A) for a ball grid array (BGA) coupling; in other embodiments, the second level interconnects 130 may include solder paste contacts to provide land grid array (LGA) interconnects, or any other suitable interconnect. In some embodiments, the circuit board 133 may include one or more components disposed thereon (not shown). The circuit board 133 may include conductive pathways that allow power, ground, and other electrical signals to move between the circuit board 133 and the substrate 102 as well as between the circuit board 133 and the die 114, as known in the art.

Although a single die 114 is illustrated in FIG. 1, this is simply an example, and the microelectronic assembly 100 may include one or more dies 114. The dies may perform any suitable functionality, and may include processing devices, memory, communications devices, sensors, or any other computing components or circuitry. For example, the dies may include a central processing unit (CPU), a platform controller hub (PCH), a dynamic random access memory (DRAM), a graphic processing unit (GPU), and a field programmable gate array (FPGA).

Although FIG. 1 illustrates a single IC package (e.g., substrate 102 with die 114) disposed on the circuit board 133, this is simply for ease of illustration and multiple IC packages with multiple dies may be disposed on the circuit board 133. In some embodiments, the circuit board 133 may be a PCB (e.g., a motherboard). In some embodiments, the circuit board 133 may be another IC package, and the microelectronic assembly 100 may be a package-on-package structure. In some embodiments, the circuit board 133 may be an interposer, and the microelectronic assembly 100 may be a package-on-interposer structure.

Many of the elements of the microelectronic assembly 100 of FIG. 1 are included in other ones of the accompanying figures; the discussion of these elements is not repeated when discussing these figures, and any of these elements may take any of the forms disclosed herein. Some of the elements of the microelectronic assembly 100 of FIG. 1 are not included in other ones of the accompanying figures for simplicity, but a microelectronic assembly 100 may include these omitted elements. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP. For example, the microelectronic assemblies 100 disclosed herein may include one or more dies 114 and one or more stiffeners 180.

FIG. 2A is a side, cross-sectional view of a microelectronic assembly 100, in accordance with various embodiments. The microelectronic assembly 100 may include a substrate 102 with dies 114-1, 114-2 and a stiffener 180 disposed thereon. The dies 114-1, 114-2 may be electrically coupled to the second surface 170-2 of the substrate 102 by first level interconnects 120 and the stiffener 180 may be coupled to a bottom surface 170-1 of the substrate 102. FIG. 2B is a bottom view of the substrate 102 and the stiffener 180 of the microelectronic assembly of FIG. 2A. FIG. 2B illustrates another example arrangement for a stiffener 180 including four sections positioned along a perimeter 115 of the substrate 102 that do not substantially form a ring or a frame around a perimeter 115 of the substrate 102. As shown in FIG. 2B, the interior portion 113 includes the footprint under the dies 114-1, 114-2.

FIG. 3A is a side, cross-sectional view of a microelectronic assembly 100, in accordance with various embodiments. The microelectronic assembly 100 may include a substrate 102 with a die 114 and a stiffener 180 disposed thereon. The die 114 may be electrically coupled to the second surface 170-2 of the substrate 102 by first level interconnects 120 and the stiffener 180 may be coupled to a bottom surface 170-1 of the substrate 102. FIG. 3B is a bottom view of the substrate 102 and the stiffener 180 of the microelectronic assembly of FIG. 3A. FIG. 3B illustrates another example arrangement for a stiffener 180 positioned at least partially within the interior portion 113 (e.g., at least partially within a footprint of the die 114). As shown in FIG. 3B, a stiffener 180 may include five sections along perpendicular axes of the substrate 102. In some embodiments, the stiffener 180 along perpendicular axes of the substrate 102 may include less than five sections. For example, as shown in FIG. 3C, a stiffener 180 may include four sections along perpendicular axes of the substrate 102. In another example, as shown in FIG. 3D, a stiffener 180 may include three sections along perpendicular axes of the substrate 102.

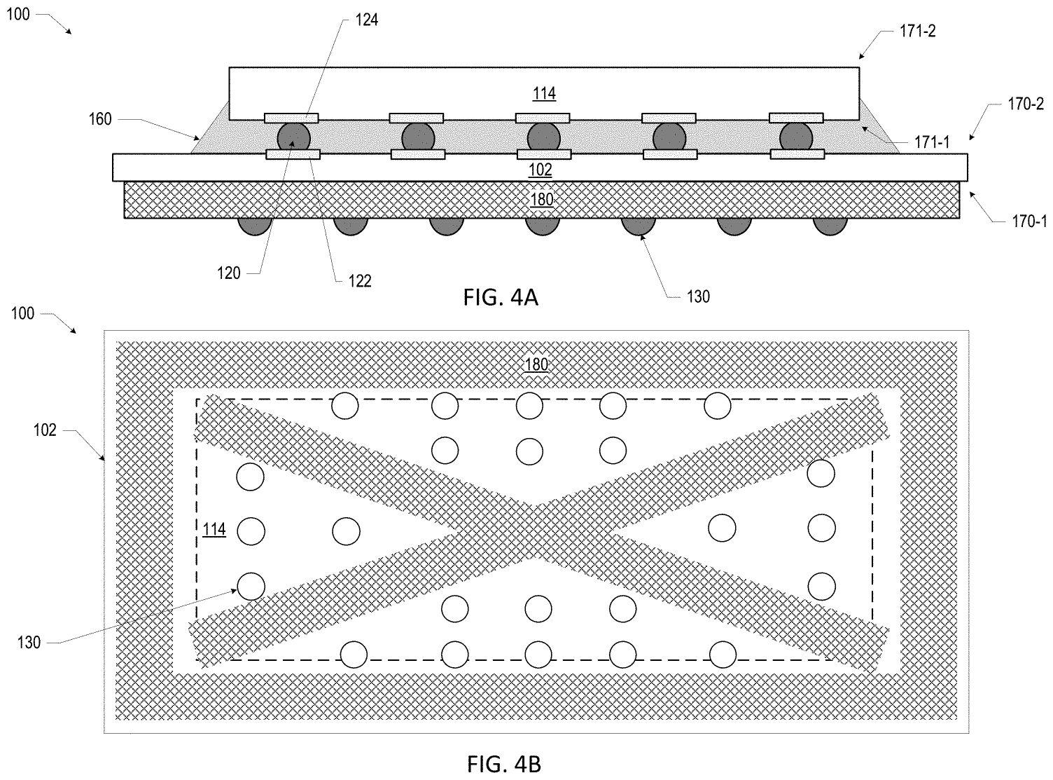

FIG. 4A is a side, cross-sectional view of a microelectronic assembly 100, in accordance with various embodiments. The microelectronic assembly 100 may include a substrate 102 with a die 114 and a stiffener 180 disposed thereon. The die 114 may be electrically coupled to the second surface 170-2 of the substrate 102 by first level interconnects 120 and the stiffener 180 may be coupled to a bottom surface 170-1 of the substrate 102. FIG. 4B is a bottom view of the substrate 102 and the stiffener 180 of the microelectronic assembly of FIG. 4A. FIG. 4B illustrates another example arrangement for a stiffener 180 positioned along a perimeter 115 and at least partially within the interior portion 113 (e.g., at least partially within a footprint of the die 114). As shown in FIG. 4B, a stiffener 180 may include a ring along a perimeter 115 of the substrate 102 and one or more sections along non-perpendicular axes of the substrate 102. In some embodiments, the stiffener 180 along non-perpendicular axes of the substrate 102 may include two or more sections. In some embodiments, the stiffener 180 may be a continuous element that includes the ring and the non-perpendicular crossing sections. In some embodiments, the ring portion of the stiffener 180 may include two or more sections, as described above with reference to FIG. 1.

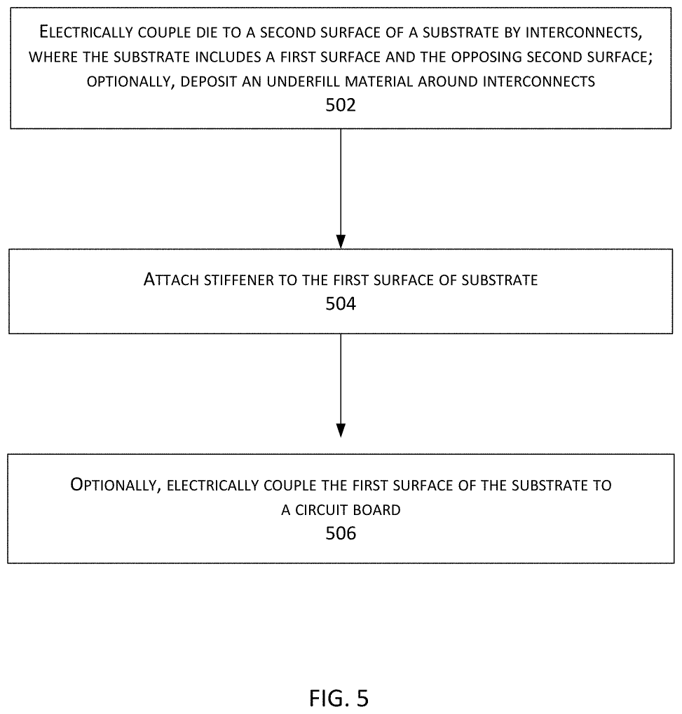

FIG. 5 is a flow diagram of an example method of manufacturing a microelectronic assembly, in accordance with various embodiments. At 502, a die 114 and other components may be electrically coupled to a top surface (e.g., a second surface 170-2) of a substrate 102 by forming first level interconnects 120. Any suitable method may be used to place the die 114, for example, automated pick-and-place. In some embodiments, the first level interconnects 120 may include solder. In such embodiments, the assembly may be subjected to a solder reflow process during which solder components of the interconnects 120 melt and bond to mechanically and electrically couple the die 114 to the top surface 170-2 of the package substrate 102. In some embodiments, an underfill material 160 may be deposited around the interconnects 120. The underfill material 160 may include any suitable material, including as described above with reference to FIG. 1, and may be dispensed using any suitable process, including capillary underfill or molded underfill and subsequently cured. At 504, a stiffener 180 may be attached or secured to a bottom surface (e.g., a first surface 170-1) of the substrate 102. The stiffener 180 may be attached using any suitable technique, as described above with reference to FIG. 1. A size and shape of the stiffener 180 may be determined based on a desired counterbalance for warpage experienced by the substrate 102 without the stiffener 180. At 506, a circuit board may be electrically coupled to the first surface 170-1 of the substrate 102 by forming second level interconnects 130. In some embodiments, an underfill material may be dispensed around the second level interconnects 130.

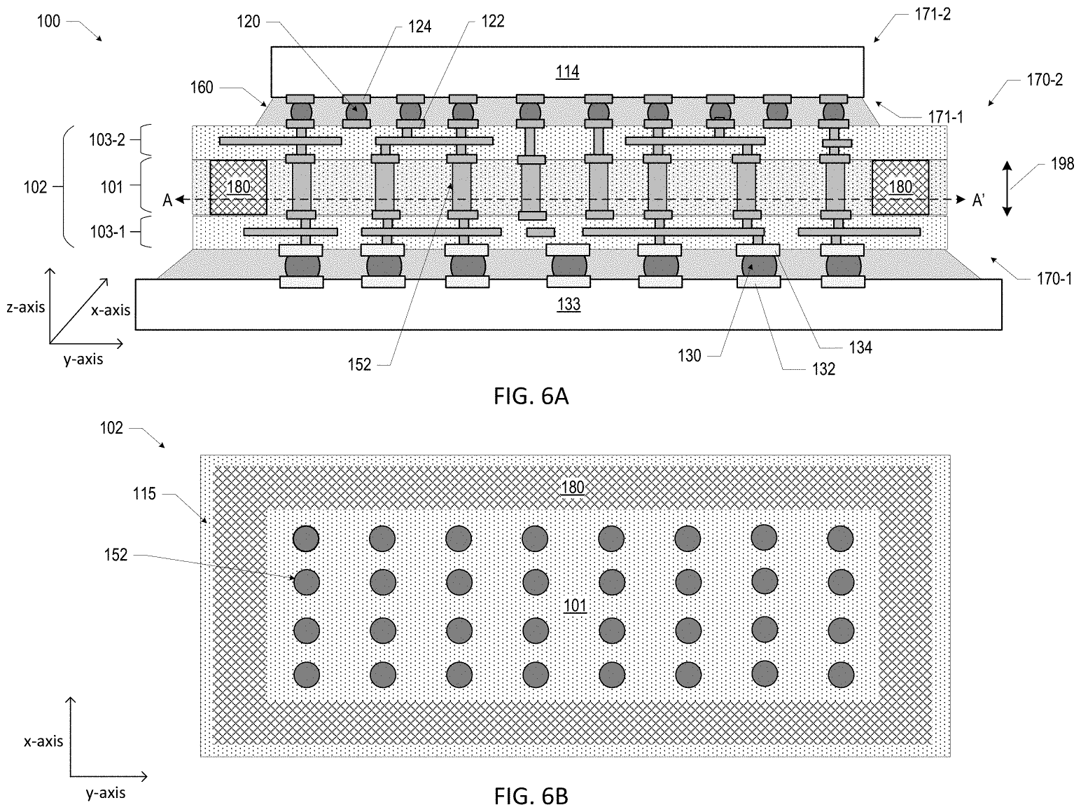

FIG. 6A is a side, cross-sectional view of a microelectronic assembly 100, in accordance with various embodiments. The microelectronic assembly 100 may include a die 114 disposed on a substrate 102 that includes a core 101 and a stiffener 180 disposed within the core 101. For example, the substrate 102 may be an UTC substrate including a core 101 with buildup layers 103-1, 103-2 (e.g., a dielectric material with conductive pathways through the dielectric material, as shown) on a bottom and a top surface of the core 101. In some embodiments, the stiffener 180 may be coupled to a ground source through the conductive pathways in the first and/or second buildup layers 103-1, 103-2. The core 101 may be formed of any suitable material, including glass, a fiber-reinforced epoxy, an organic dielectric material, such as an epoxy, or a phenolic resin or polymide resin reinforced with glass, aramid, or nylon. The core 101 may have any suitable dimensions, including a thickness 198 between 0.1 millimeters and 1.4 millimeters. The substrate 102 may further include one or more plated through hole (PTH) via 152 electrically coupling the bottom and top buildup layers 103-1, 103-2. A PTH via 152 may be formed by mechanically drilling or laser drilling through the core 101 to form a through hole. The through hole may be plated with metal, such as copper, and filled (or plugged) with a conductive material, such as copper, or a dielectric material, such as epoxy, to form the PTH via 152. The PTH vias 152 may have any suitable dimensions, including a diameter (e.g., a cross-section dimension) between 65 microns and 200 microns. In some embodiments, a PTH via 152 may have a pad size between 90 microns and 350 microns. FIG. 6B is a cross-sectional view of the substrate 102 along the A-A′ line of FIG. 6A showing the stiffener 180 as a ring along a perimeter 115 of the core 101. As described above with reference to FIG. 1, the stiffener 180 may not be a continuous ring but instead may be formed by a plurality of sections that substantially form a ring or a frame around a perimeter of the core 101. The stiffener 180 in the core 101 may be formed of any suitable material and any suitable size and shape, as described above with reference to FIG. 1. The stiffener 180 may be formed using any suitable process, such as crack-free laser drilling, to form openings and subsequently depositing a material of the stiffener 180 in the openings. In some embodiments, the stiffener 180 may be formed when the PTH vias 152 are formed. Laser drilling techniques generally form openings having a conical profile where the opening is larger towards the drilling side. Other examples of suitable processes include a laser ablation process, a mediablasting or sandblasting process, an ultrasonic drilling process, or an etching process (such as a chemical wet etching process or a dry reactive ion etching process), or a combination of these processes. In some embodiments, the openings for the stiffener 180 may be formed by exposing a photoimageable glass to ultraviolet (UV) light. For example, a mask material may be used to define the area of the photoimageable glass that is exposed to ultraviolet light. The masked photoimageable glass may be exposed to ultraviolet light and heated to an elevated temperature causing a change of the structural and/or chemical properties of the area exposed to ultraviolet light, such that the exposed area may have a higher etch rate than the unexposed area of the photoimageable glass. In some embodiments, the openings for the stiffener 180 may be etched in the exposed area of the photoimageable glass using an acid, such as hydrofluoric acid (HF), ethylenediamine pyrocatechol, potassium hydroxide/isopropyl alcohol, or tetramethylammonium hydroxide. The material of the stiffener 180 may be deposited in the opening using any suitable process. For example, a conductive material may be deposited using electroplating, sputtering, or electroless plating.

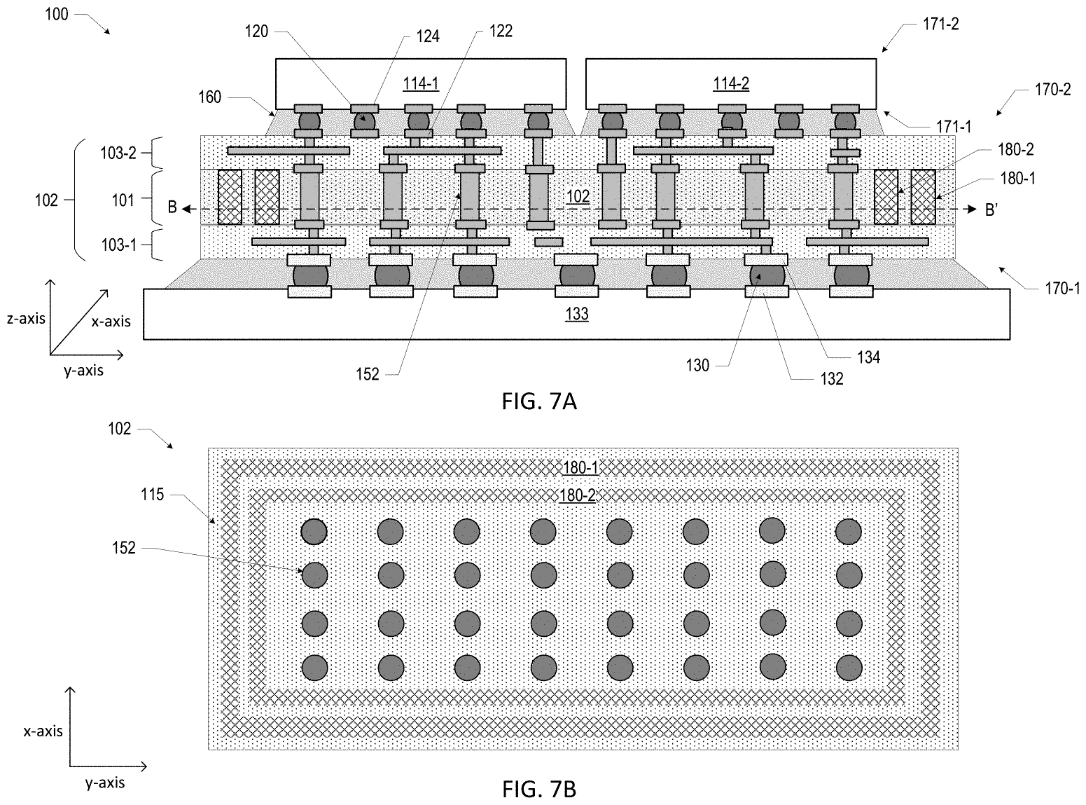

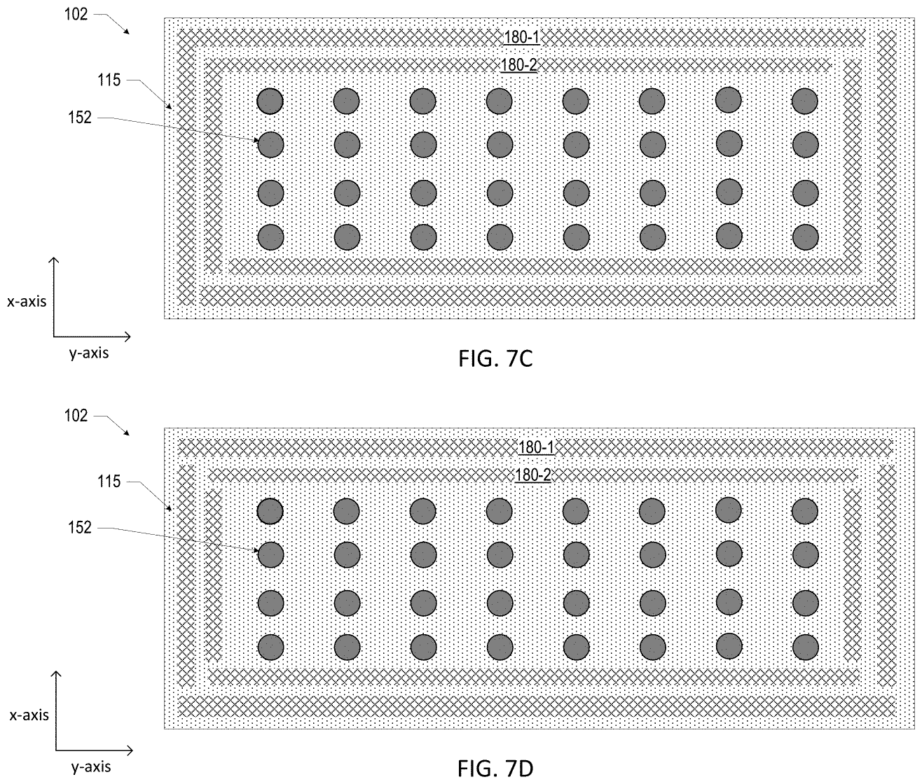

FIG. 7A is a side, cross-sectional view of a microelectronic assembly 100, in accordance with various embodiments. The microelectronic assembly 100 may include a die 114 disposed on a substrate 102 that includes a core 101 and a stiffener 180 disposed within the core 101. As shown in FIG. 7A, the stiffener 180 may include a first stiffener 180-1 and a second stiffener 180-2. FIG. 7B is a cross-sectional view of the substrate 102 along the B-B′ line of FIG. 7A showing the first stiffener 180-1 as an outer ring along a perimeter 115 of the core 101 and the second stiffener 180-2 as an inner ring along a perimeter 115 of the core 101, such that the first and second stiffeners 180-1, 180-2 are concentric rings. The first and second stiffeners 180-1, 180-2 may have any suitable dimensions, and, for example, may cumulatively have dimensions as described above with reference to FIG. 1. In some embodiments, as shown FIGS. 7C and 7D, the first and second stiffeners 180-1, 180-2 may not be a continuous ring but instead may be formed by a plurality of elements or sections that substantially form a ring or a frame around a perimeter of the core 101. FIG. 7C is a cross-sectional view of the substrate 102 along the B-B′ line of FIG. 7A showing another arrangement of a first stiffener 180-1 as an outer ring along a perimeter 115 of the core 101 and a second stiffener 180-2 as an inner ring along a perimeter 115 of the core 101, where the first and second stiffeners 180-1, 180-2 are two L-shaped sections that substantially form the concentric rings. In some embodiments, a stiffener 180 may include two or more elements substantially forming a ring along a perimeter of the core 101. FIG. 7D is a cross-sectional view of the substrate 102 along the B-B′ line of FIG. 7A showing another arrangement of a first stiffener 180-1 as an outer ring along a perimeter 115 of the core 101 and a second stiffener 180-2 as an inner ring along a perimeter 115 of the core 101, where the first and second stiffeners 180-1, 180-2 are four linear sections that substantially form the concentric rings. In some embodiments, a stiffener 180 may include four or more elements substantially forming a ring along a perimeter of the core 101.

FIG. 8A is a side, cross-sectional view of a microelectronic assembly 100, in accordance with various embodiments. The microelectronic assembly 100 may include a microelectronic subassembly 104 on a substrate 102, where the microelectronic subassembly 104 includes an interposer 105 with dies 114-1, 114-2 and a stiffener 180 disposed thereon. The interposer 105 may be made of any suitable material, such as an epoxy resin, a polyimide resin, a polyester resin, a BT resin, or polyethylene terephthalate (PET). The stiffener 180 may be formed of any suitable material and may be any suitable size and shape, as described above with reference to FIG. 1. For example, the stiffener 180 may be a continuous ring along a perimeter of the interposer 105. In some embodiments, a thickness 191 (e.g., z-height) of the stiffener 180 may be equal to between 20% and 120% of a total z-height of the die 114 and the interconnect 121. In some embodiments, the dies 114-1, 114-2 may have different thicknesses (not shown), such that the total z-height of the die 114 plus the interconnect 121 is equal to the thicker die, or if more than two dies 114, the thickest die, plus the z-height of the interconnect 121 (e.g., if a z-height of die 114-1 is greater than a z-height of die 114-2, a thickness 191 is equal to between 20% and 120% of the z-height of die 114-1, the thicker die, and a maximum thickness of the interconnect 121. In some embodiments, a width 193 (e.g., x-axis for a section along a length (e.g., y-axis) of the interposer 105) is equal to between 5% and 20% of a width or a length of the interposer 105. The microelectronic subassembly 104 may include a bottom surface (e.g., a first surface 172-1) and an opposing top surface (e.g., a second surface 172-2). The dies 114-1, 114-2 may be electrically coupled to a top surface of the interposer 105 by interconnects 121. The interconnects 121 may be surrounded by an underfill material 160 (e.g., the underfill material 160 may be disposed between the dies 114-1, 114-2 and the top surface of the interposer 105). The interposer 105 may have conductive contacts 123 on a top surface and conductive contacts 125 on a bottom surface. In some embodiments, the interconnects 121 may include solder, as shown in FIG. 8. In other embodiments, the interconnects 121 may include copper pillars, wirebonds, metal-to-metal interconnects, or any other suitable interconnects surrounded by an underfill material 160. In some embodiments, an insulating material 135 may be disposed around the dies 114-1, 114-2 and stiffener 180 (e.g., between the dies 114-1, 114-2 and the stiffener 180). In some embodiments, the insulating material 135 of the microelectronic subassembly 104 may be a dielectric material, such as an organic dielectric material, a fire retardant grade 4 material (FR-4), a BT resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics). In some embodiments, the insulating material 135 of the microelectronic subassembly 104 may be a mold material, such as an organic polymer with inorganic silica particles. The conductive contacts 125 on a bottom surface of the interposer 105 (e.g., a first surface 172-1 of the microelectronic subassembly 104) may be coupled to the conductive contacts 122 on a top surface (e.g., the second surface 170-2) of the substrate 102 by first level interconnects 120. In some embodiments, the first level interconnects 120 may be surrounded by an underfill material 160. In some embodiments, conductive contacts on a bottom surface 170-1 of the substrate 102 may be coupled to a circuit board, for example, as shown in FIG. 1.

FIG. 8B is a side, cross-sectional view of a microelectronic assembly 100, in accordance with various embodiments. The microelectronic assembly 100 may include a microelectronic subassembly 104 on a substrate 102, where the microelectronic subassembly 104 includes an interposer 105 with dies 114-1, 114-2 and a stiffener 180 disposed thereon. As shown in FIG. 8B, the stiffener 180 may include a first stiffener 180-1 having a first material and a second stiffener 180-2 on the first stiffener 180-1, the second stiffener 180-2 having a second material different from the first material. The first and second materials of the first and second stiffeners 180-1, 180-2 may include any suitable materials, as described above with reference to FIG. 1. The first and second stiffeners 180-1, 180-2 may be attached to the interposer 105, and to each other, using any suitable technique, as described above with reference to FIG. 1. For example, depending on the composition of the first and second materials, the first and second stiffeners 180-1, 180-2 may be attached by thermo-compression, soldering, gluing, fusion bonding, deposition, and/or implantation. The first and second stiffeners 180-1, 180-2 may have any suitable dimensions, and may cumulatively have dimensions as described above with reference to FIG. 8A. For example, the first stiffener 180-1 may have a first thickness 191-1 and the second stiffener 180-2 may have a second thickness 191-2, where a sum of the first and second thicknesses 191-1, 191-2 equals an overall thickness 191.

FIG. 8C is a side, cross-sectional view of a microelectronic assembly 100, in accordance with various embodiments. The microelectronic assembly 100 may include a microelectronic subassembly 104 on a substrate 102, where the microelectronic subassembly 104 includes an interposer 105 with dies 114-1, 114-2 and a stiffener 180 disposed thereon. As shown in FIG. 8C, the stiffener 180 may be on a top surface (e.g., a second surface 171-2) of the dies 114-1, 114-2 and the insulating material 135. The stiffener 180 may have any suitable size and shape, as described above with reference to FIG. 1. In some embodiments, the stiffener 180 is a ring along a perimeter of the interposer 105. In some embodiments, the stiffener 180 covers a top surface area (e.g., x-y area) of the interposer 105. In some embodiments, a thickness 195 (e.g., z-height) of the stiffener 180 may be between 20% and 120% of a thickness of a die 114. In some embodiments, where the dies 114-1, 114-2 have different thicknesses (not shown), a thickness 195 of the stiffener 180 may be between 20% and 120 percent of the thicker die 114. The stiffener 180 may include any suitable materials, as described above with reference to FIG. 1. The stiffener 180 may be attached to the top surface of the dies 114-1, 114-2 and the insulating material 135, using any suitable technique, as described above with reference to FIG. 1. Although FIG. 8 illustrates a microelectronic subassembly 104 having two dies 114-1, 114-2, a microelectronic assembly may have any number and arrangement of dies 114 and may further include other components coupled to the interposer 105.

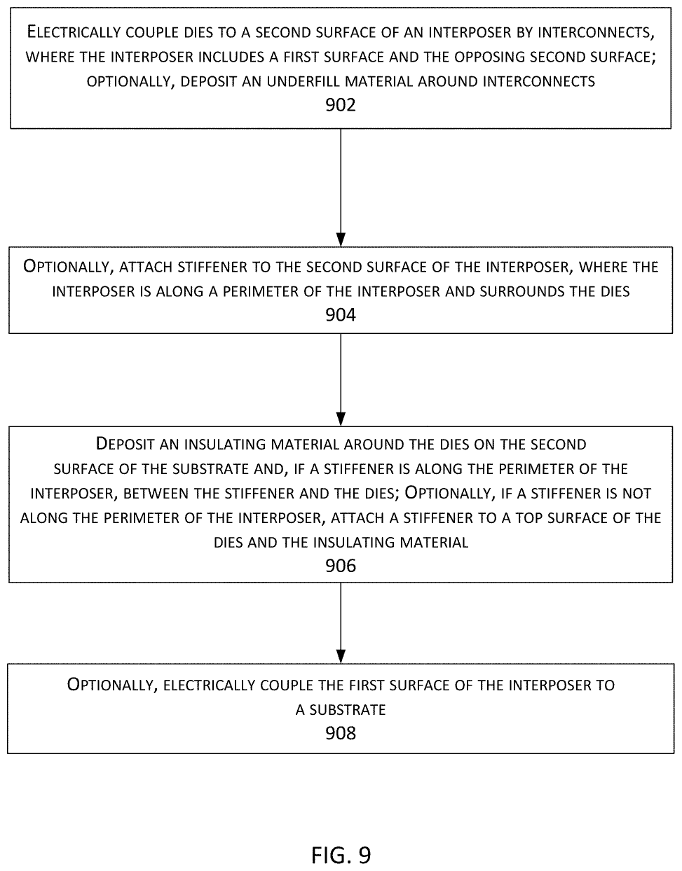

FIG. 9 is a flow diagram of an example method of manufacturing a microelectronic assembly, in accordance with various embodiments. At 902, a first die 114-1 and a second die 114-2 (and/or other components) may be electrically coupled to a top surface (e.g., a second surface) of an interposer 105 by forming interconnects 121. Any suitable method may be used to place the dies 114-1, 114-2, for example, automated pick-and-place. In some embodiments, the interconnects 121 may include solder. In such embodiments, the assembly may be subjected to a solder reflow process during which solder components of the interconnects 121 melt and bond to mechanically and electrically couple the dies 114-1, 114-2 to the top surface of the interposer 105. In some embodiments, an underfill material 160 may be deposited around the interconnects 121. The underfill material 160 may include any suitable material, including as described above with reference to FIG. 1, and may be dispensed using any suitable process, including capillary underfill or molded underfill and subsequently cured. At 904, a stiffener 180 may be attached or secured to a top surface of the interposer 105 (e.g., along a perimeter of the interposer 105 surrounding the dies 114-1, 114-2). A size and shape of the stiffener 180 may be determined based on a desired counterbalance for warpage experienced by the assembly without the stiffener 180. At 906, an insulating material 135 may be deposited around the dies 114-1, 114-2 and if a stiffener 180 is positioned along a perimeter of the interposer 105, the insulating material may be deposited between the dies 114-1, 114-2 and the stiffener 180. Optionally, if a stiffener is not attached along a perimeter of the interposer 105, a stiffener 180 may be attached to a top surface of the dies 114-1, 114-2 and the insulating material 135. At 908, a substrate may be electrically coupled to the bottom surface of the interposer 105 (e.g., a first surface 172-1 of the microelectronic subassembly 104) by forming first level interconnects 120. Further operations may be performed, such as electrically coupling the substrate to a circuit board.

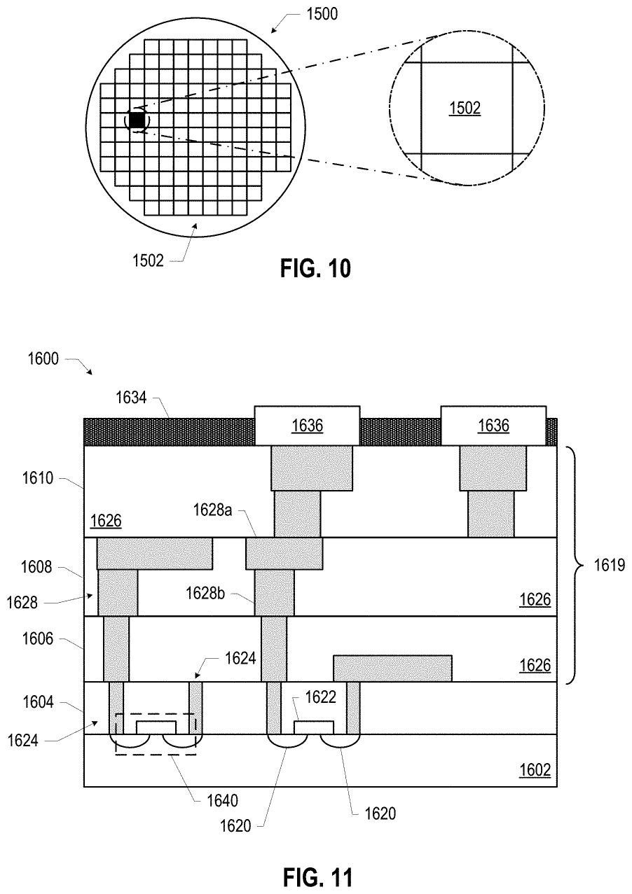

The microelectronic assemblies 100 disclosed herein may be included in any suitable electronic component. FIGS. 10-12 illustrate various examples of apparatuses that may include, or be included in, any of the microelectronic assemblies 100 disclosed herein.

FIG. 10 is a top view of a wafer 1500 and dies 1502 that may be included in any of the microelectronic assemblies 100 disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 11, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 13) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include others of the dies 114, and the wafer 1500 is subsequently singulated.

FIG. 11 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 10). The IC device 1600 may be formed on a die substrate 1602 (e.g., the wafer 1500 of FIG. 10) and may be included in a die (e.g., the die 1502 of FIG. 10). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 10) or a wafer (e.g., the wafer 1500 of FIG. 10).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 11 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 11. Although a particular number of interconnect layers 1606-1610 is depicted in FIG. 11, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 11. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 11. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 11, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components. The conductive contacts 1636 may serve as the conductive contacts 122 or 124, as appropriate.

In some embodiments in which the IC device 1600 is a double-sided die (e.g., like the die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636. These additional conductive contacts may serve as the conductive contacts 122 or 124, as appropriate.

In other embodiments in which the IC device 1600 is a double-sided die (e.g., like the die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636. These additional conductive contacts may serve as the conductive contacts 122 or 124, as appropriate.

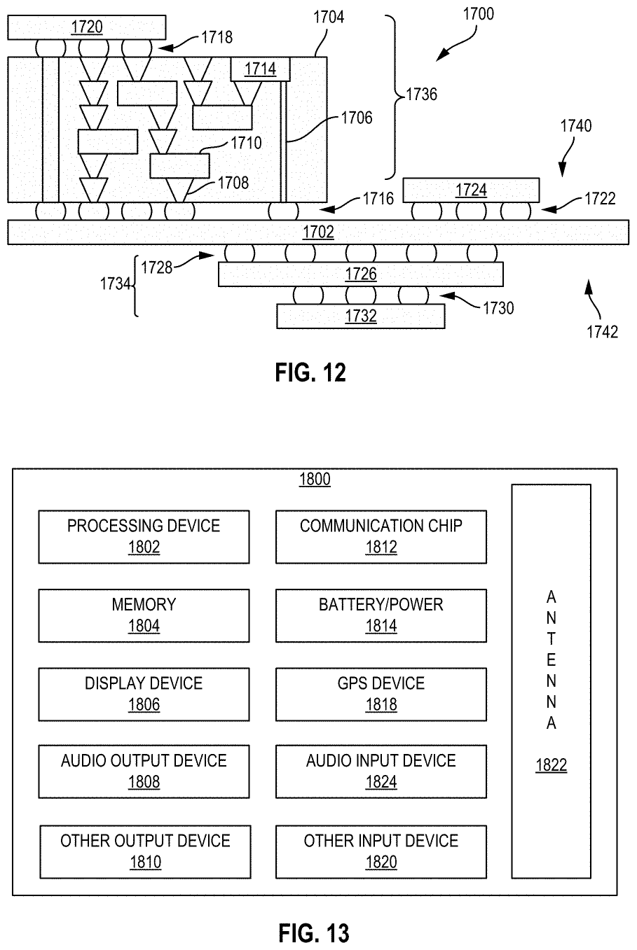

FIG. 12 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 12 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 12), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 12, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 10), an IC device (e.g., the IC device 1600 of FIG. 11), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 12, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 12 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 13 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 13 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 13, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-M RAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.
Example 1A is a microelectronic assembly, including a substrate having a first surface and an opposing second surface; a die electrically coupled to the second surface of the substrate by an interconnect; and a stiffener attached to the first surface of the substrate configured to mitigate warpage of the die.
Example 2A may include the subject matter of Example 1A, and may further specify that the stiffener is along a portion of a perimeter of the substrate.
Example 3A may include the subject matter of Example 1A, and may further specify that the stiffener is along two or more edges of the substrate.
Example 4A may include the subject matter of Example 1A, and may further specify that the stiffener is along a central axis of the substrate.
Example 5A may include the subject matter of Example 1A, and may further specify that the stiffener is along perpendicular axes of the substrate.
Example 6A may include the subject matter of Example 1A, and may further specify that the stiffener is along intersecting, non-perpendicular axes.
Example 7A may include the subject matter of Example 1A, and may further specify that the stiffener is at least partially within a footprint of the die.
Example 8A may include the subject matter of any one of Examples 1A-7A, and may further specify that is equal to between 20% and 80% of a thickness of the interconnect.
Example 9A may include the subject matter of any one of Examples 1A-7A, and may further specify that a total volume of the stiffener is between 50 percent and 110 percent of a total volume of the die.
Example 10A may include the subject matter of any one of Examples 1A-7A, and may further specify that a width of the stiffener is between 5 percent and 20 percent of a length of the substrate and a length of the stiffener is between 50 percent and 100 percent of the length of the substrate.
Example 11A1 may include the subject matter of any one of Examples 1A-10A, and may further specify that an area of the substrate is between 30 millimeters by 30 millimeters and 150 millimeters by 150 millimeters.
Example 11A2 may include the subject matter of any one of Examples 1A-10A, and may further specify that the stiffener is configured to mitigate warpage of the die.
Example 12A is a microelectronic assembly, including a package substrate having a first surface and an opposing second surface; a die electrically coupled to the second surface of the substrate; and a plurality of elements attached to the first surface of the package substrate configured to mitigate warpage of the die.
Example 13A may include the subject matter of Example 12A, and may further specify that a material of the plurality of elements includes silicon, glass, a metal, a metal alloy, or a ceramic.
Example 14A may include the subject matter of Example 13A, and may further specify that the material of the plurality of elements is a metal or a metal alloy including one or more of titanium, zirconium, palladium, platinum, and nickel.
Example 15A may include the subject matter of Example 13A, and may further specify that the material of the plurality of elements is silicon.
Example 16A may include the subject matter of Example 13A, and may further specify that the material of the plurality of elements has a co-efficient of thermal expansion (CTE) between 2e-6 ppm/° C. and 17e-6 ppm/° C.
Example 17A may include the subject matter of any one of Examples 12A-16A, and may further specify that the plurality of elements are along a perimeter of the package substrate.
Example 18A may include the subject matter of any one of Examples 12A-16A, and may further specify that the plurality of elements are along perpendicular axes of the package substrate.
Example 19A may include the subject matter of any one of Examples 12A-16A, and may further specify that the plurality of elements are at least partially within a footprint of the die.
Example 20A may include the subject matter of any one of Examples 12A-16A, and may further specify that the plurality of elements are not within a footprint of the die.
Example 21A may include the subject matter of any one of Examples 12A-20A, and may further include a circuit board electrically coupled to the first surface of the package substrate.
Example 22A is a computing device, including a circuit board; and an integrated circuit (IC) package electrically coupled to the circuit board, wherein the IC package comprises a substrate having a first surface and an opposing second surface; a die electrically coupled to the second surface of the substrate; and a stiffener attached to the first surface of the substrate.
Example 23A may include the subject matter of Example 22A, and may further specify that the stiffener is along a perimeter of the substrate.
Example 24A may include the subject matter of Example 22A, and may further specify that the stiffener is along two or more edges of the substrate.
Example 25A may include the subject matter of Example 22A, and may further specify that the stiffener is along a central axis of the substrate.
Example 26A may include the subject matter of Example 22A, and may further specify that the stiffener is along perpendicular axes of the substrate.
Example 27A may include the subject matter of Example 22A, and may further specify that the stiffener is along intersecting, non-perpendicular axes.
Example 28A may include the subject matter of Example 22A, and may further specify that the stiffener is at least partially within a footprint of the die.
Example 29A may include the subject matter of Example 22A, and may further specify that the stiffener is not within a footprint of the die.
Example 30A may include the subject matter of any one of Examples 22A-29A, and may further specify that a total volume of the stiffener is between 50 percent and 110 percent of a total volume of the die.
Example 31A may include the subject matter of any one of Examples 22A-29A, and may further specify that a width of the stiffener is between 5 percent and 15 percent of a length of the substrate and a length of the stiffener is between 50 percent and 100 percent of the length of the substrate.
Example 32A may include the subject matter of any one of Examples 22A-31A, and may further specify that a material of the stiffener includes silicon, glass, a metal, a metal alloy, or a ceramic.
Example 33A may include the subject matter of any one of Examples 22A-32A, wherein the die is selected from the group consisting of a central processing unit, a platform controller hub, a memory die, a field programmable gate array silicon die, and graphic processing unit.
Example 34A may include the subject matter of any one of Examples 22A-33A, and may further specify that the microelectronic assembly is included in a server device.
Example 35A may include the subject matter of any one of Examples 22A-33A, and may further specify that the microelectronic assembly is included in a portable computing device.
Example 36A may include the subject matter of any one of Examples 22A-33A, and may further specify that the microelectronic assembly is included in a wearable computing device.
Example 37A is a method for fabricating a microelectronic assembly, the method including electrically coupling a die to a second surface of a package substrate, wherein the package substrate includes the second surface and a first surface opposite the second surface; and attaching a stiffener to the first surface of the package substrate, wherein the stiffener is configured to mitigate warpage of the die.
Example 38A may include the subject matter of Example 37A, and may further specify that a material of the stiffener includes glass, silicon, a metal, a metal alloy, or a ceramic.
Example 39A may include the subject matter of Examples 37A or 38A, and may further specify that the stiffener is along a perimeter of the package substrate.
Example 40A may include the subject matter of Examples 37A or 38A, and may further specify that the stiffener is along two or more edges of the substrate.
Example 41A may include the subject matter of Examples 37A or 38A, and may further specify that the stiffener is along a central axis of the substrate.
Example 42A may include the subject matter of Examples 37A or 38A, and may further specify that the stiffener is along perpendicular axes of the substrate.
Example 43A may include the subject matter of Examples 37A or 38A, and may further specify that the stiffener is along intersecting, non-perpendicular axes.
Example 44A may include the subject matter of Examples 37A or 38A, and may further specify that the stiffener is at least partially within a footprint of the die.
Example 45A may include the subject matter of Examples 37A or 38A, and may further specify that the stiffener is not within a footprint of the die.
Example 1B is a microelectronic assembly, including a substrate, the substrate including a core; and a stiffener in the core, wherein the stiffener is along a perimeter of the core; and a die electrically coupled to the substrate.
Example 2B may include the subject matter of Example 1B, and may further specify that the stiffener is a continuous ring along a perimeter of the core.
Example 3B may include the subject matter of Example 1B, and may further specify that the stiffener includes two or more elements substantially forming a ring along a perimeter of the core.
Example 4B may include the subject matter of Example 3B, and may further specify that the stiffener includes two L-shaped elements substantially forming a ring along a perimeter of the core.
Example 5B may include the subject matter of Example 1B, and may further specify that the stiffener includes four or more elements substantially forming a ring along a perimeter of the core.
Example 6B may include the subject matter of Example 5B, and may further specify that the stiffener includes four or more linear elements substantially forming a ring along a perimeter of the core.
Example 7B may include the subject matter of any one of Examples 1B-6B, and may further specify that a thickness of the stiffener is between Example 0.1 millimeters and Example 1.4 millimeters.
Example 8B may include the subject matter of any one of Examples 1B-7B, and may further specify that the core further includes a plated through hole (PTH) via.
Example 9B may include the subject matter of any one of Examples 1B-8B, and may further specify that a material of the stiffener includes silicon, glass, a metal, an amorphous metal alloy, or a ceramic.
Example 10B may include the subject matter of Example 9B, wherein the material of the stiffener includes a metal, or an amorphous metal alloy.
Example 11B may include the subject matter of any one of Examples 1B-10B, and may further specify that the stiffener is a first stiffener, and the substrate further includes a second stiffener in the core, wherein the second stiffener is along a perimeter of the core and is concentric with the first stiffener.
Example 12B is a microelectronic assembly, including a substrate having a first surface and an opposing second surface, the substrate including a core and a stiffener within the core along a perimeter of the core; a die electrically coupled to the second surface of the substrate; and a circuit board electrically coupled to the first surface of the substrate.
Example 13B may include the subject matter of Example 12B, and may further specify that the stiffener is a continuous ring along a perimeter of the core.
Example 14B may include the subject matter of Example 12B, and may further specify that the stiffener includes two or more elements substantially forming a ring along a perimeter of the core.
Example 15B may include the subject matter of Example 14B, and may further specify that the stiffener includes two L-shaped elements substantially forming a ring along a perimeter of the core.
Example 16B may include the subject matter of Example 12B, and may further specify that the stiffener includes four or more elements substantially forming a ring along a perimeter of the core.
Example 17B may include the subject matter of Example 16B, and may further specify that the stiffener includes four or more linear elements substantially forming a ring along a perimeter of the core.
Example 18B may include the subject matter of any one of Examples 12B-17B, and may further specify that a material of the stiffener includes silicon, glass, a metal, an amorphous metal alloy, or a ceramic.
Example 19B may include the subject matter of any one of Examples 12B-18B, and may further specify that the stiffener is a first stiffener, and the substrate further includes a second stiffener within the core, wherein the second stiffener is along a perimeter of the core and is concentric with the first stiffener.
Example 20B is a method for fabricating a microelectronic assembly, the method including forming a stiffener in a core of a substrate, wherein the substrate includes a first surface and an opposing second surface, and wherein the stiffener is along a perimeter of the core of the substrate and is configured to mitigate warpage; and electrically coupling a die to the second surface of the substrate.
Example 21B may include the subject matter of Example 20B, and may further specify that a material of the stiffener includes glass, silicon, a metal, a metal alloy, or a ceramic.
Example 22B may include the subject matter of Examples 20B or 21B, and may further specify that the stiffener is a continuous ring along a perimeter of the core.
Example 23B may include the subject matter of Examples 20B or 21B, and may further specify that the stiffener includes two or more elements substantially forming a ring along a perimeter of the core.
Example 24B may include the subject matter of Examples 20B or 21B, and may further specify that the stiffener includes four or more elements substantially forming a ring along a perimeter of the core.
Example 25B may include the subject matter of any one of Examples 20B-24B, and may further specify that the stiffener is a first stiffener, and the method further includes forming a second stiffener in the core of the substrate, wherein the second stiffener is along a perimeter of the core of the substrate and is concentric with the first stiffener.
Example 1C is a microelectronic assembly, including a substrate; and a microelectronic subassembly electrically coupled to the substrate by interconnects, the microelectronic subassembly including an interposer having a surface; a first die electrically coupled to the surface of the interposer; a second die electrically coupled to the surface of the interposer; and a stiffener ring coupled to the surface of the interposer along a perimeter of the interposer.
Example 2C may include the subject matter of Example 1C, and may further include an insulating material around the first and second dies and between the first and second dies and the stiffener ring.
Example 3C may include the subject matter of Examples 1C or 2C, and may further specify that a material of the stiffener includes glass, silicon, a metal, a metal alloy, or a ceramic.
Example 4C may include the subject matter of any one of Examples 1C-3C, and may further specify that a thickness of the stiffener is equal to between 20% and 120% of a thickness of the first die or the second die.
Example 5C may include the subject matter of Example 2C, and may further specify that the insulating material includes a dielectric material or a mold material.
Example 6C may include the subject matter of any one of Examples 1C-5C, and may further include an underfill material around the interconnects.
Example 7C may include the subject matter of any one of Examples 1C-6C, and may further specify that the stiffener is a first stiffener having a first material, and the microelectronic assembly and may further include a second stiffener on the first stiffener, the second stiffener having a second material different from the first material.
Example 8C may include the subject matter of any one of Examples 1C-7C, and may further include a circuit board electrically coupled to the substrate.
Example 9C is a microelectronic assembly, including a substrate; and a microelectronic subassembly including an interposer having a first surface and an opposing second surface, the first surface of the interposer electrically coupled to the substrate; a first die electrically coupled to the second surface of the interposer by first interconnects; a second die electrically coupled to the second surface of the interposer by second interconnects; an insulating material on the second surface of the interposer around and between the first and second dies; and a stiffener coupled to a top surface of the first die, the second die, and the insulating material.
Example 10C may include the subject matter of Example 9C, and may further specify that a material of the stiffener includes glass, silicon, a metal, a metal alloy, or a ceramic.
Example 11C may include the subject matter of Examples 9C or 10C, and may further specify that a thickness of the stiffener is equal to between 20% and 120% of a thickness of the first die or the second die.
Example 12C may include the subject matter of any one of Examples 9C-11C, and may further specify that the insulating material includes a dielectric material or a mold material.
Example 13C may include the subject matter of any one of Examples 9C-12C, and may further include an underfill material around the first and second interconnects.
Example 14C may include the subject matter of any one of Examples 9C-13C, and may further include a circuit board electrically coupled to the substrate.
Example 15C is a method for fabricating a microelectronic assembly, the method including electrically coupling a first die to surface of an interposer; electrically coupling a second die to surface of the interposer; attaching a stiffener to the surface of the interposer, wherein the stiffener is along a perimeter of the interposer; and depositing an insulating material around the first and second dies and between the first and second dies and the stiffener.
Example 16C may include the subject matter of Example 15C, and may further specify that a material of the stiffener includes glass, silicon, a metal, a metal alloy, or a ceramic.
Example 17C may include the subject matter of Examples 15C or 16C, and may further specify that a thickness of the stiffener is equal to between 20% and 120% of a thickness of the first die or the second die.
Example 18C may include the subject matter of any one of Examples 15C-17C, and may further specify that a material of the interposer includes an epoxy resin, a polyimide resin, a polyester resin, a bismaleimide triazine (BT) resin, or polyethylene terephthalate (PET).
Example 19C may include the subject matter of any one of Examples 15C-18C, and may further specify that the insulating material includes a dielectric material or a mold material.
Example 20C may include the subject matter of any one of Examples 15C-19C, and may further specify that the interposer includes a first surface and an opposing second surface, and the first die, the second die, and the stiffener are on the second surface, and the method and may further include electrically coupling the first surface of the interposer to a substrate.
Example 21C is a method for fabricating a microelectronic assembly, the method including electrically coupling a first die to surface of an interposer; electrically coupling a second die to surface of the interposer; depositing an insulating material on the surface of the interposer around the first and second dies; and attaching a stiffener to a top surface of the first die, the second die, and the insulating material.
Example 22C may include the subject matter of Example 21C, and may further specify that a material of the stiffener includes glass, silicon, a metal, a metal alloy, or a ceramic.
Example 23C may include the subject matter of Examples 21C or 22C, and may further specify that a thickness of the stiffener is equal to between 20% and 120% of a thickness of the first die or the second die.
Example 24C may include the subject matter of any one of Examples 21C-23C, and may further specify that a material of the interposer includes an epoxy resin, a polyimide resin, a polyester resin, a bismaleimide triazine (BT) resin, or polyethylene terephthalate (PET).
Example 25C may include the subject matter of any one of Examples 21C-24C, and may further specify that the insulating material includes a dielectric material or a mold material.
Example 26C may include the subject matter of any one of Examples 21C-25C, and may further specify that the interposer includes a first surface and an opposing second surface, and the first die, the second die, and the insulating material are on the second surface, and the method and may further include electrically coupling the first surface of the interposer to a substrate.

1. A microelectronic assembly, comprising:
a substrate; and
a microelectronic subassembly electrically coupled to the substrate by interconnects, the microelectronic subassembly including:
an interposer having a surface;
a first die electrically coupled to the surface of the interposer;
a second die electrically coupled to the surface of the interposer; and
a stiffener ring coupled to the surface of the interposer along a perimeter of the interposer.

2. The microelectronic assembly of claim 1, further comprising:
an insulating material around the first and second dies and between the first and second dies and the stiffener ring.

3. The microelectronic assembly of claim 1, wherein a material of the stiffener includes glass, silicon, a metal, a metal alloy, or a ceramic.

4. The microelectronic assembly of claim 1, wherein a thickness of the stiffener is equal to between 20% and 120% of a thickness of the first die or the second die.

5. The microelectronic assembly of claim 2, wherein the insulating material includes a dielectric material or a mold material.

6. The microelectronic assembly of claim 1, further comprising:
an underfill material around the interconnects.

7. The microelectronic assembly of claim 1, wherein the stiffener is a first stiffener having a first material, and the microelectronic assembly further comprising:
a second stiffener on the first stiffener, the second stiffener having a second material different from the first material.

8. The microelectronic assembly of claim 1, further comprising:
a circuit board electrically coupled to the substrate.

9. A microelectronic assembly, comprising:
a substrate; and
a microelectronic subassembly including:
an interposer having a first surface and an opposing second surface, the first surface of the interposer electrically coupled to the substrate;
a first die electrically coupled to the second surface of the interposer by first interconnects;
a second die electrically coupled to the second surface of the interposer by second interconnects;
an insulating material on the second surface of the interposer around and between the first and second dies; and
a stiffener coupled to a top surface of the first die, the second die, and the insulating material.

10. The microelectronic assembly of claim 9, wherein a material of the stiffener includes glass, silicon, a metal, a metal alloy, or a ceramic.

11. The microelectronic assembly of claim 9, wherein a thickness of the stiffener is equal to between 20% and 120% of a thickness of the first die or the second die.

12. The microelectronic assembly of claim 9, wherein the insulating material includes a dielectric material or a mold material.

13. The microelectronic assembly of claim 9, further comprising:
an underfill material around the first and second interconnects.

14. The microelectronic assembly of claim 9, further comprising:
a circuit board electrically coupled to the substrate.

15. A method for fabricating a microelectronic assembly, the method comprising:
electrically coupling a first die to surface of an interposer;
electrically coupling a second die to surface of the interposer;
attaching a stiffener to the surface of the interposer, wherein the stiffener is along a perimeter of the interposer; and
depositing an insulating material around the first and second dies and between the first and second dies and the stiffener.

16. The method of claim 15, wherein a material of the stiffener includes glass, silicon, a metal, a metal alloy, or a ceramic.

17. The method of claim 15, wherein a thickness of the stiffener is equal to between 20% and 120% of a thickness of the first die or the second die.

18. The method of claim 15, wherein a material of the interposer includes an epoxy resin, a polyimide resin, a polyester resin, a bismaleimide triazine (BT) resin, or polyethylene terephthalate (PET).

19. The method of claim 15, wherein the insulating material includes a dielectric material or a mold material.

20. The method of claim 15, wherein the interposer includes a first surface and an opposing second surface, and the first die, the second die, and the stiffener are on the second surface, and the method further comprising:
electrically coupling the first surface of the interposer to a substrate.
